(19) United States
(12) Patent Application Publication
(10) Pub. No.: US 2026/0045306 A1
(43) Pub. Date: Feb. 12, 2026

(54) SEMICONDUCTOR MEMORY DEVICE AND METHOD OF DRIVING SEMICONDUCTOR MEMORY DEVICE

(71) Applicant: Kioxia Corporation, Tokyo (JP)

(72) Inventors: Ryota SHIMADA, Yokohama (JP); Shinji SUZUKI, Sagamihara (JP)

(73) Assignee: Kioxia Corporation, Tokyo (JP)

(21) Appl. No.: 19/074,740

(22) Filed: Mar. 10, 2025

(30) Foreign Application Priority Data
Aug. 9, 2024 (JP) 2024-134078

(51) Int. Cl. G11C 16/26; G11C 16/04; G11C 16/30

(52) U.S. Cl. CPC G11C 16/26; G11C 16/0483; G11C 16/30

(57) ABSTRACT

A semiconductor memory device includes strings each including memory cells connected in series; first select transistors connected to one end of the strings; second select transistors connected to the other end of the strings; first control lines commonly provided to the strings and connected to gates of the memory cells; first selection lines connected to gates of the first select transistors and each corresponding to a first unit having one string; second selection lines connected to gates of the second select transistors and corresponding to a second unit including a plurality of the first units; and a driver configured to provide a voltage for the plurality of first selection lines, causing a difference between a first non-selection voltage and a second non-selection voltage.

### CROSS-REFERENCE TO RELATED APPLICATION

This application is based upon and claims the benefit of priority from Japanese Patent Application No. 2024-134078, filed Aug. 9, 2024, the entire contents of which are incorporated herein by reference.

### FIELD

Embodiments described herein relate generally to a semiconductor memory device and a method of driving the semiconductor memory device.

### BACKGROUND

A NAND-type flash memory includes select transistors at both ends of strings of a plurality of memory cells connected in series. In a data read operation, the select transistors connected to strings not to be read transition to a non-conductive state. However, in the non-conductive select transistors, an increase in leakage current or an increase in hot carriers becomes a problem.

### DESCRIPTION OF THE DRAWINGS

FIG. 1 is a block diagram illustrating an example of a configuration of a semiconductor memory device according to an embodiment;

FIG. 2 is a circuit diagram illustrating an example of a circuit configuration of a memory cell array;

FIG. 3 is a cross-sectional view illustrating an example of the configuration of the semiconductor memory device according to the embodiment;

FIG. 4 is a plan view illustrating a stacked body;

FIG. 5 is a cross-sectional view illustrating a memory cell having a three-dimensional structure;

FIG. 6 is a cross-sectional view illustrating the memory cell having a three-dimensional structure;

FIG. 7 is a plan view illustrating a plane of the memory cell array and a method of controlling a read operation according to the embodiment;

FIG. 8 is a diagram illustrating a NAND string in a data read operation;

FIG. 9 is a diagram illustrating a state of the NAND string and an energy level of a channel; and

FIG. 10 is a diagram illustrating a state of the NAND string and an energy level of the channel.

### DETAILED DESCRIPTION

Embodiments provide a semiconductor memory device and a method of driving the semiconductor memory device capable of reducing leakage current or hot carriers of select transistors in a non-conductive state in a data read operation.

In general, according to one embodiment, a semiconductor memory device includes a plurality of strings, each of the plurality of strings including a plurality of memory cells connected in series; a plurality of first select transistors connected to one end of the plurality of strings, respectively; a plurality of second select transistors connected to the other end of the plurality of strings, respectively; a plurality of first control lines commonly provided to the plurality of strings and are connected to respective gates of the memory cells of the plurality of strings; a plurality of first selection lines connected to respective gates of the plurality of first select transistors and each correspond to a first unit that includes one of the plurality of the strings; a plurality of second selection lines connected to respective gates of the plurality of second select transistors and correspond to a second unit that includes a plurality of the first units; and a driver configured to provide, in a data read operation, a voltage for the plurality of first selection lines, causing a difference between a first non-selection voltage and a second non-selection voltage, wherein the first non-selection voltage is applied to one of the first selection lines not selected in a selected second unit which is selected to be read among a plurality of the second units, and the second non-selection voltage is applied to the first selection lines in one or more non-selected second units not to be read among the plurality of second units.

Hereinafter, embodiments of the present disclosure will be described with reference to the accompanying drawings. The embodiments do not limit the present disclosure. The drawings are schematic or conceptual. In the specification and the drawings, the same elements are represented by the same reference numerals and signs.

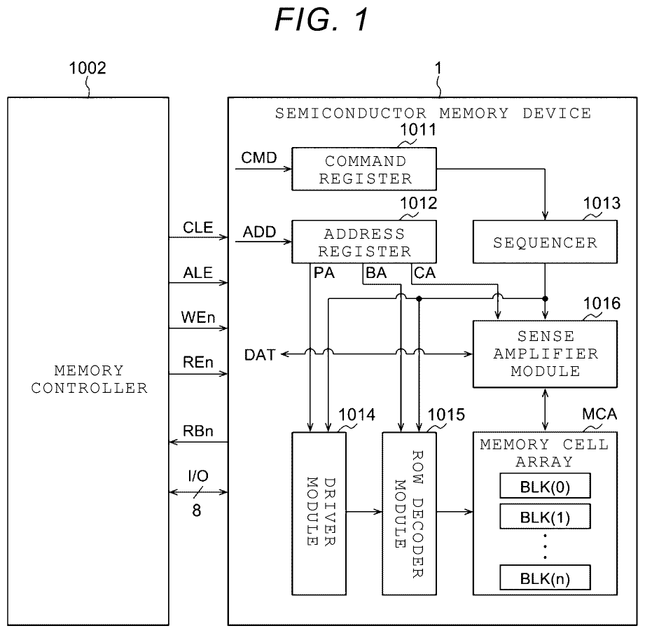

FIG. 1 is a block diagram illustrating an example of a configuration of a semiconductor memory device according to the present embodiment. A semiconductor memory device 1 is, for example, a NAND-type flash memory capable of storing data in a non-volatile manner, and is controlled by an external memory controller 1002. Communication between the semiconductor memory device 1 (hereinafter, referred to as a memory 1) and the memory controller 1002 supports, for example, the NAND interface standard.

As illustrated in FIG. 1, the memory 1 includes, for example, a memory cell array MCA, a command register 1011, an address register 1012, a sequencer 1013, a driver module 1014, a row decoder module 1015, and a sense amplifier module 1016.

The memory cell array MCA includes a plurality of blocks BLK(0) to BLK(n) (n is an integer of 1 or more). The block BLK is a set of a plurality of memory cells capable of storing data in a non-volatile manner, and is used, for example, as an erase unit of data. The memory cell array MCA is provided with a plurality of bit lines and a plurality of word lines. Each memory cell is associated with, for example, one bit line and one word line.

The command register 1011 stores a command CMD that is received by the memory 1 from the memory controller 1002. The command CMD includes, for example, an instruction to cause the sequencer 1013 to execute a read operation, a write operation, an erase operation, and the like.

The address register 1012 stores address information ADD that is received by the memory 1 from the memory controller 1002. The address information ADD includes, for example, a block address BA, a page address PA, and a column address CA. For example, the block address BA, the page address PA, and the column address CA are respectively used to select the block BLK, the word line, and the bit line.

The sequencer 1013 controls operations of the entire memory 1. For example, the sequencer 1013 controls the driver module 1014, the row decoder module 1015, the sense amplifier module 1016, and the like based on the command CMD stored in the command register 1011 to execute the read operation, the write operation, the erase operation, and the like.

The driver module 1014 generates voltages used in the read operation, the write operation, the erase operation, and the like. The driver module 1014 applies, for example, voltages to word lines, drain side select gate lines SGD, and source side select gate lines SGS based on the page address PA stored in the address register 1012.

The row decoder module 1015 includes a plurality of row decoders. The row decoder selects one block BLK in the corresponding memory cell array MCA based on the block address BA stored in the address register 1012. The row decoder transfers, for example, a voltage applied to a signal line corresponding to the selected word line, to the selected word line in the selected block BLK.

The sense amplifier module 1016 applies a desired voltage to each bit line as a data line in response to write data DAT received from the memory controller 1002 in the write operation. In the read operation, the sense amplifier module 1016 determines the data stored in the memory cell based on the voltage of the bit line and transfers the determination result to the memory controller 1002 as read data DAT.

The memory 1 and the memory controller 1002 described above may be combined to configure one semiconductor memory device. Examples of such a semiconductor memory device include memory cards such as an SD™ card, a solid state drive (SSD), and the like.

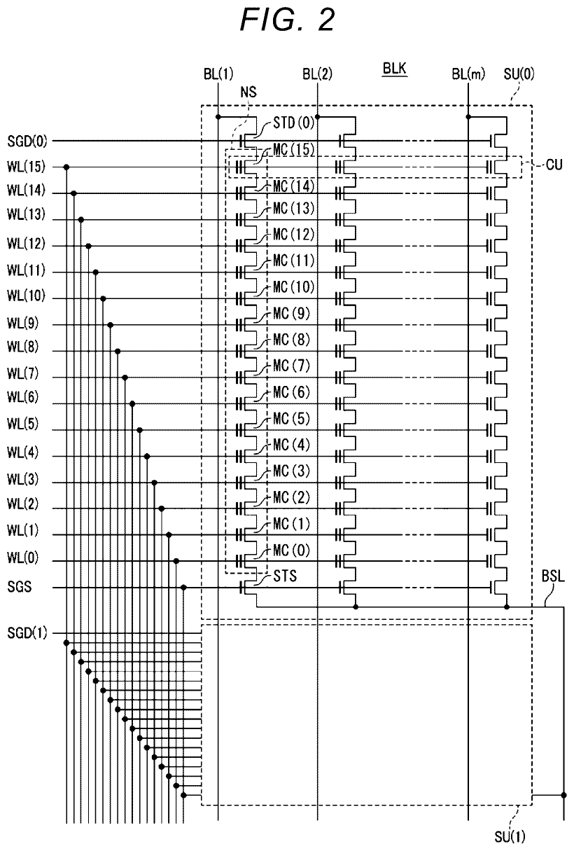

FIG. 2 is a circuit diagram illustrating an example of a circuit configuration of the memory cell array MCA. One block BLK is extracted from the plurality of blocks BLK in the memory cell array MCA. The block BLK includes a plurality of string units SU(0) to SU(k) (k is an integer of 1 or more).

Each string unit SU(i) (i=0 to k) includes a plurality of NAND strings NS associated with bit lines BL(0) to BL(m) (m is an integer of 1 or more). Each NAND string NS includes, for example, memory cells MC(0) to MC(15) connected in series. Select transistors STD (i) and STS are each connected to each end of the NAND string NS. The memory cell MC includes a control gate and a charge storage layer, and stores data in a non-volatile manner. Each of the select transistors STD (i) and STS is used to select a string unit SU during various operations.

In each NAND string NS, the memory cells MC(0) to MC(15) are connected in series. A drain of the select transistor STD (i) is connected to the associated bit line BL. A source of the select transistor STD (i) is connected to the memory cell MC(15) at one end of the memory cells MC(0) to MC(15) connected in series. A drain of the select transistor STS is connected to the memory cell MC(0) at the other end of the memory cells MC(0) to MC(15) connected in series. A source of the select transistor STS is connected to a source layer BSL. The sources of a plurality of select transistors STS are connected in common to the source layer BSL as a reference voltage layer to which a reference voltage (for example, ground voltage) is applied.

Word lines WL(0) to WL(15) are provided in common to the plurality of NAND strings NS in the same block BLK. Accordingly, the control gates of the memory cells MC(0) to MC(15) in the same block BLK are respectively connected in common to the word lines WL(0) to WL(15).

In the same string unit SU(i), gates of the plurality of select transistors STD (i) are connected in common to a drain side select gate line SGD (i) as a first selection line. That is, the drain side select gate line SGD (i) is connected to the gates of the plurality of select transistors STD and corresponds to each string unit SU(i).

In the same block BLK, gates of the plurality of select transistors STS are connected in common to a source side select gate line SGS as a second selection line. The source side select gate line SGS is connected to the gates of the plurality of select transistors STS, and corresponds to each block BLK. Thereby, the word lines WL(0) to WL(15) and the source side select gate line SGS are driven for each block BLK. On the other hand, the drain side select gate line SGD (i) is driven for each string unit SU(i).

In the circuit configuration of the memory cell array MCA described above, the bit line BL is shared by the NAND strings NS to which the same column address is assigned in each string unit SU. The source layer BSL is shared, for example, between the plurality of blocks BLK.

A set of the plurality of memory cells MC connected to the common word line WL in one string unit SU is referred to as, for example, a cell unit CU. For example, a storage capacity of the cell unit CU including the memory cells MC each storing 1 bit of data is defined as “1 page data”. The cell unit CU may have a storage capacity of 2 pages of data or more according to the number of bits of data stored in the memory cells MC.

It should be noted that the memory cell array MCA in the memory 1 according to the present embodiment is not limited to the circuit configuration described above. For example, the number of memory cells MC and the number of select transistors STD and STS in each NAND string NS may be freely selected. The number of string units SU in each block BLK may also be freely selected.

Hereinafter, the select transistors STD and STS are also referred to as a drain side select transistor STD and a source side select transistor STS, respectively. “(i)” may be omitted.

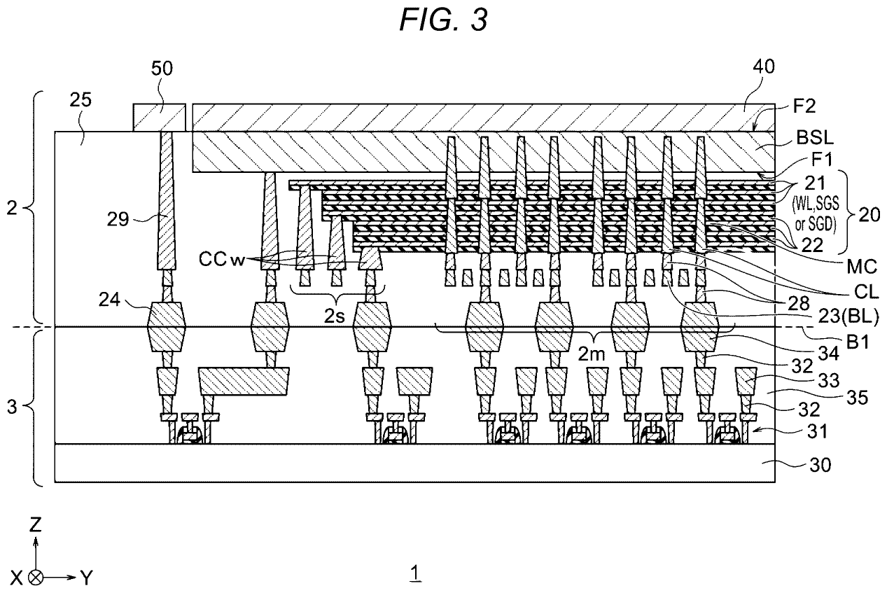

FIG. 3 is a cross-sectional view illustrating an example of a configuration of the memory 1 according to the present embodiment. Hereinafter, a stacking direction of a stacked body 20 is defined as a Z direction. A direction that intersects with the Z direction, for example, a direction perpendicular to the Z direction is defined as a Y direction. A direction that intersects with both the Z direction and the Y direction, for example, a direction perpendicular to the Z direction and the Y direction is defined as an X direction. FIG. 3 shows the memory 1 assuming that a +Z direction is an upward direction. However, here, a description may be given assuming that a −Z direction is the upward direction. In the present specification, the +Z direction is an example of a first direction.

The memory 1 includes an array chip 2 provided with a memory cell array and a CMOS chip 3 provided with a CMOS circuit. The array chip 2 and the CMOS chip 3 are bonded on a bonding surface B1, and are electrically connected to each other through wiring bonded at the bonding surface. FIG. 3 shows a state where the array chip 2 is provided on the CMOS chip 3. The memory cell array is hereinafter represented by 2m.

The CMOS chip 3 includes a substrate 30, transistors 31, vias 32, wirings 33 and 34, and an interlayer insulating film 35.

The substrate 30 is, for example, a semiconductor substrate such as a silicon substrate. The transistors 31 are an N-type metal oxide semiconductor field effect transistor (MOSFET) or a P-type MOSFET provided on the substrate 30. The transistors 31 configure, for example, a complementary MOS (CMOS) circuit that controls the memory cell array of the array chip 2. The plurality of transistors 31 configure logic circuits such as a sense amplifier, a row decoder, and a column decoder. Semiconductor elements such as resistor elements and capacitor elements other than the transistor 31 may be formed on the substrate 30.

The vias 32 electrically connect between the transistors 31 and the wiring 33, or between the wiring 33 and the wiring 34. The wirings 33 and 34 configure a multilayer wiring structure in the interlayer insulating film 35. The wiring 34 is embedded in the interlayer insulating film 35 and is exposed to be substantially coplanar with the surface of the interlayer insulating film 35. The wirings 33 and 34 are electrically connected to the transistors 31 and the like. Metal such as copper or tungsten is used for the vias 32 and the wirings 33 and 34. The interlayer insulating film 35 covers and protects the transistors 31, the vias 32, and the wirings 33 and 34. An insulating film such as a silicon oxide film is used for the interlayer insulating film 35.

The array chip 2 includes the stacked body 20, columnar bodies CL, the source layer BSL, a metal layer 40, contact plugs CCw, a contact plug 29, a bonding pad 50, wirings 23 and 24, vias 28, and an interlayer insulating film 25.

The stacked body 20 is provided above the transistor 31 and is located in the +Z direction of the substrate 30. The stacked body 20 is formed by alternately stacking a plurality of electrode films 21 and a plurality of insulating films 22 along the Z direction. The stacked body 20 and the columnar bodies CL configure the memory cell array. Conductive metal such as tungsten is used for the electrode film 21. An insulating film such as a silicon oxide film is used for the insulating film 22. The insulating films 22 insulate the electrode films 21 from each other. That is, the plurality of electrode films 21 are stacked in an insulated state from each other. The number of stacked electrode films 21 and the number of stacked insulating films 22 each are freely selected. The insulating film 22 may be, for example, a porous insulating film or an air gap.

One or a plurality of electrode films 21 at each of the upper end and the lower end of the stacked body 20 in the Z direction function as each of the source side select gate line SGS and the drain side select gate line SGD. The electrode film 21 between the source side select gate line SGS and the drain side select gate line SGD functions as the word line WL. The source side select gate line SGS is provided closer to the source layer BSL in the stacked body 20. The drain side select gate line SGD is provided farther from the source layer BSL in the stacked body 20.

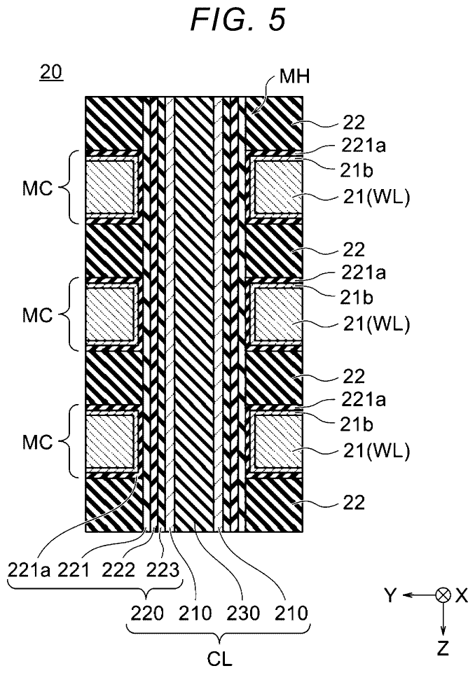

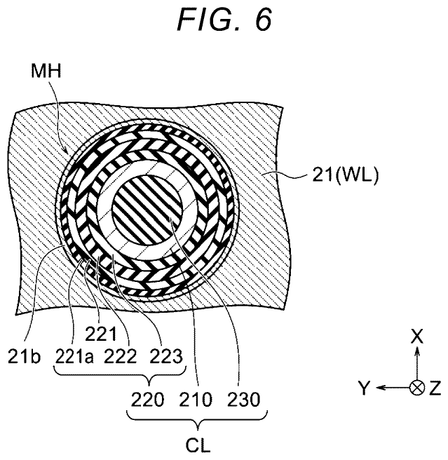

The select transistors STD in FIG. 2 are each connected between semiconductor bodies (210 in FIGS. 5 and 6) of the plurality of columnar bodies CL and the plurality of bit lines BL. The select transistors STS are each connected between the semiconductor bodies of the plurality of columnar bodies CL and the common source layer BSL.

The stacked body 20 includes the plurality of columnar bodies CL. The columnar bodies CL are provided in the stacked body 20, extend through the stacked body 20 in the stacking direction of the stacked body 20 (Z direction), and are provided in a range from the vias 28 to the source layer BSL, in which the vias 28 are connected to bit lines 23. One columnar body CL corresponds to one NAND string NS(i). That is, one NAND string NS(i) is configured with one columnar body CL and a plurality of word lines WL. For example, one end of the NAND string NS(i) is connected to the bit line BL through the via 28. For example, the other end of the NAND string NS(i) is connected in common to the source layer BSL. The bit line BL is the wiring 23 that is provided under the stacked body 20 and extends in the X direction. Therefore, the bit line BL is also referred to as the bit line 23. It should be noted that FIG. 3 shows a case where the columnar body CL is formed to be divided into two stages in the Z direction. However, the columnar body CL may be formed to be divided into three or more stages.

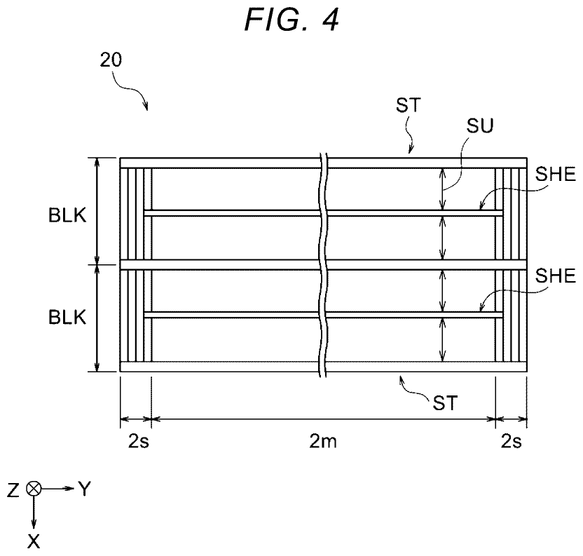

Further, as will be described later with reference to FIG. 4, a plurality of slits ST are provided in the stacked body 20. The slits ST extend in the Y direction and penetrate the stacked body 20 in the stacking direction of the stacked body 20 (Z direction). The slits ST are filled with an insulating film such as a silicon oxide film, and the insulating film is formed in a plate shape. The slits ST electrically divide the electrode films 21 of the stacked body 20. Alternatively, an inner wall of the slit ST may be covered with an insulating film such as a silicon oxide film, and a conductive material may be embedded inside the insulating film. Then, the conductive material may also function as a source wiring connected to the source layer BSL.

The source layer BSL is provided on the stacked body 20. The source layer BSL corresponds to the stacked body 20. The stacked body 20 (memory cell array 2m) is provided on a surface F1 side of the source layer BSL, and the metal layer 40 is provided on a surface F2 opposite to the surface F1. The source layer BSL is connected in common to the ends of the plurality of columnar bodies CL, and applies a common source voltage to the plurality of columnar bodies CL in the same memory cell array 2m. That is, the source layer BSL functions as a common source electrode of the memory cell array 2m including the plurality of blocks BLK. A conductive material such as doped polysilicon is used for the source layer BSL. A metal material having a lower resistance than the source layer BSL, such as copper, aluminum, or tungsten is used for the metal layer 40.

On the other hand, the bonding pad 50 is provided above the surface F2 of the source layer BSL in a region in which the source layer BSL is not provided. The bonding pad 50 is connected to a metal wire or the like (not illustrated in the drawing) and is supplied with power or receives a signal from the outside of the memory 1. The bonding pad 50 is connected to one end of the contact plug 29 in the Z direction. The bonding pad 50 is connected to the transistors 31 of the CMOS chip 3 through the contact plug 29, the wiring 24, and the wiring 34. The external power supplied from the bonding pad 50 is supplied to the transistors 31. Alternatively, a signal is supplied to the transistors 31 or the memory cell array 2m through the bonding pad 50.

The contact plugs CCw are provided in a peripheral portion of the stacked body 20 and extend in the Z direction in the interlayer insulating film 25. The contact plugs CCw are electrically connected between the electrode films 21 (word lines WL) and the wiring 24. The contact plugs CCw are provided in a staircase portion 2s in which the electrode films 21 are formed in a staircase shape at the end of the stacked body 20, and are electrically connected to each of the electrode films 21. The contact plug CCw is provided to transmit a word line voltage from the CMOS chip 3 to each electrode film 21. Metal such as copper or tungsten is used for the contact plug CCw.

In the present embodiment, the array chip 2 and the CMOS chip 3 are separately formed and are bonded to each other on the bonding surface B1. Therefore, the array chip 2 does not include the transistors 31. Further, the CMOS chip 3 does not include the stacked body 20 (memory cell array 2m).

The vias 28, the wiring 23, and the wiring 24 are provided under the stacked body 20. The wirings 23 and 24 are embedded in the interlayer insulating film 25. The wiring 24 is exposed to be substantially coplanar with the surface of the interlayer insulating film 25. The wirings 23 and 24 are electrically connected to the semiconductor bodies (210 in FIGS. 5 and 6) of the columnar bodies CL, and the like. Metal such as copper or tungsten is used for each of the vias 28, the wiring 23, and the wiring 24. The interlayer insulating film 25 covers and protects the stacked body 20, the vias 28, the wiring 23, and the wiring 24. An insulating film such as a silicon oxide film is used for the interlayer insulating film 25.

The interlayer insulating film 25 and the interlayer insulating film 35 are bonded to each other on the bonding surface B1. Therefore, the wiring 24 and the wiring 34 are bonded to each other on the bonding surface B1 to be substantially coplanar. Accordingly, the array chip 2 and the CMOS chip 3 are electrically connected to each other through the wiring 24 and the wiring 34.

FIG. 4 is a plan view illustrating the stacked body 20. The stacked body 20 includes the staircase portion 2s and the memory cell array 2m. The staircase portion 2s is provided, for example, at the end of the stacked body 20. The memory cell array 2m is interposed between or surrounded by the staircase portions 2s. The slits ST are provided from the staircase portion 2s at one end of the stacked body 20 through the memory cell array 2m to the staircase portion 2s at the other end of the stacked body 20 in the Z direction, and divide the stacked body 20 for each block BLK. An insulating material is used for the slit ST. Alternatively, the slit ST may include a source wiring electrically connected to the source layer BSL while being electrically separated from the electrode films 21 of the stacked body 20.

Slits SHE are provided in the memory cell array 2m. The slits SHE are thinner in the Z direction than the slits ST and extend substantially parallel to the slit ST in the Y direction. The slits SHE divide the electrode film 21 corresponding to the drain side select gate line SGD for each string unit SU. However, the slits SHE do not reach the electrode films 21 corresponding to the word lines WL in the Z direction and do not divide the word lines WL. An insulating film such as a silicon oxide film is used for the slit SHE.

A part of the stacked body 20 interposed between two slits ST illustrated in FIG. 4 corresponds to the block BLK. The block BLK configures, for example, a minimum unit of data erasing. The slit SHE is provided in the block BLK. A plurality of slits SHE may be provided in one block BLK. A part of the stacked body 20 between the slit ST and the slit SHE or between two adjacent slits SHE corresponds to a string unit (also referred to as a finger) SU. The drain side select gate line SGD is separated for each string unit SU by the slits SHE. Therefore, during writing and reading of data, one string unit SU in the block BLK can be set as a selected state by the drain side select gate line SGD.

Each of FIGS. 5 and 6 is a cross-sectional view illustrating a memory cell having a three-dimensional structure. The plurality of columnar bodies CL are provided in memory holes MH in the stacked body 20. Each columnar body CL penetrates the stacked body 20 from one end of the stacked body 20 along the Z direction, and is provided in a range from the inside of the stacked body 20 to the inside of the source layer BSL. Each of the plurality of columnar bodies CL includes a semiconductor body 210, a memory film 220, and a core layer 230. The columnar body CL includes the core layer 230 provided at the center thereof, the semiconductor body (semiconductor layer) 210 provided around the core layer 230, and the memory film 220 provided around the semiconductor body 210. The semiconductor body 210 extends in the stacking direction of the stacked body 20 (Z direction). The semiconductor body 210 is electrically connected to the source layer BSL. The memory film 220 is provided between the semiconductor body 210 and the electrode film 21, and is provided with a charge trapping portion. The plurality of columnar bodies CL selected one by one from each string unit are connected in common to one bit line 23 through the vias 28 in FIG. 3. Each of the columnar bodies CL is provided, for example, in the region of the memory cell array 2m.

As illustrated in FIG. 6, a shape of the memory hole MH in an XY plane is, for example, a circle or an ellipse. A block insulating film 221a configuring a part of the memory film 220 may be provided between the electrode film 21 and the insulating film 22. The block insulating film 221a is made of, for example, silicon oxide or metal oxide. One example of metal oxide is aluminum oxide. A barrier film 21b may be provided between the electrode film 21 and the insulating film 22 and between the electrode film 21 and the memory film 220. When the electrode film 21 is made of, for example, tungsten, the barrier film 21b is made of, for example, titanium nitride. The block insulating film 221a prevents back tunneling of charges from the electrode film 21 to the memory film 220 side. The barrier film 21b improves adhesion between the electrode film 21 and the block insulating film 221a.

The semiconductor body 210 has, for example, a bottomed cylindrical shape. For example, polysilicon is used for the semiconductor body 210. The semiconductor body 210 is, for example, undoped silicon. Alternatively, the semiconductor body 210 may be p-type silicon. The semiconductor body 210 serves as a channel of each of the drain side select transistor, the memory cell MC, and the source side select transistor. That is, the plurality of memory cells MC each have a storage region between the semiconductor body 210 and the electrode film 21 serving as the word line WL, and are stacked in the Z direction. One end of the plurality of semiconductor bodies 210 in the same memory cell array 2m is electrically connected in common to the source layer BSL.

The memory film 220 includes, for example, a cover insulating film 221, a charge trapping film 222, a tunnel insulating film 223, and the block insulating film 221a. A part of the memory film 220 except for the block insulating film 221a is provided between the inner wall of the memory hole MH and the semiconductor body 210. A shape of the memory film 220 is, for example, cylindrical. The charge trapping film 222 and the tunnel insulating film 223 each extend in the Z direction.

The cover insulating film 221 is provided between the insulating film 22 and the charge trapping film 222 and between the block insulating film 221a and the charge trapping film 222. The cover insulating film 221 contains, for example, silicon oxide. The cover insulating film 221 prevents the charge trapping film 222 from being etched when a sacrificial film (not illustrated in the drawing) is replaced by the electrode film 21 (replacement step).

The charge trapping film 222 is provided between the cover insulating film 221 and the tunnel insulating film 223. The charge trapping film 222 contains, for example, silicon nitride, and is provided with trap sites in which charges are trapped in the film. A part of the charge trapping film 222 interposed between the electrode film 21 serving as the word line WL and the semiconductor body 210 forms a storage area of the memory cell MC as the charge trapping portion. A threshold voltage of the memory cell MC changes depending on whether charge is trapped in the charge trapping portion or an amount of charge trapped in the charge trapping portion. Thereby, the memory cell MC stores information.

The tunnel insulating film 223 is provided between the semiconductor body 210 and the charge trapping film 222. The tunnel insulating film 223 contains, for example, silicon oxide, or silicon oxide and silicon nitride. The tunnel insulating film 223 is a potential barrier between the semiconductor body 210 and the charge trapping film 222. For example, when electrons are injected from the semiconductor body 210 to the charge trapping film 222 (write operation), and when holes are injected from the semiconductor body 210 to the charge trapping film 222 (erase operation), the electrons and the holes pass through the potential barrier of the tunnel insulating film 223 (tunneling).

The core layer 230 fills an internal space of the cylindrical semiconductor body 210. The core layer 230 has, for example, a columnar shape. The core layer 230 contains, for example, silicon oxide, and has an insulating property.

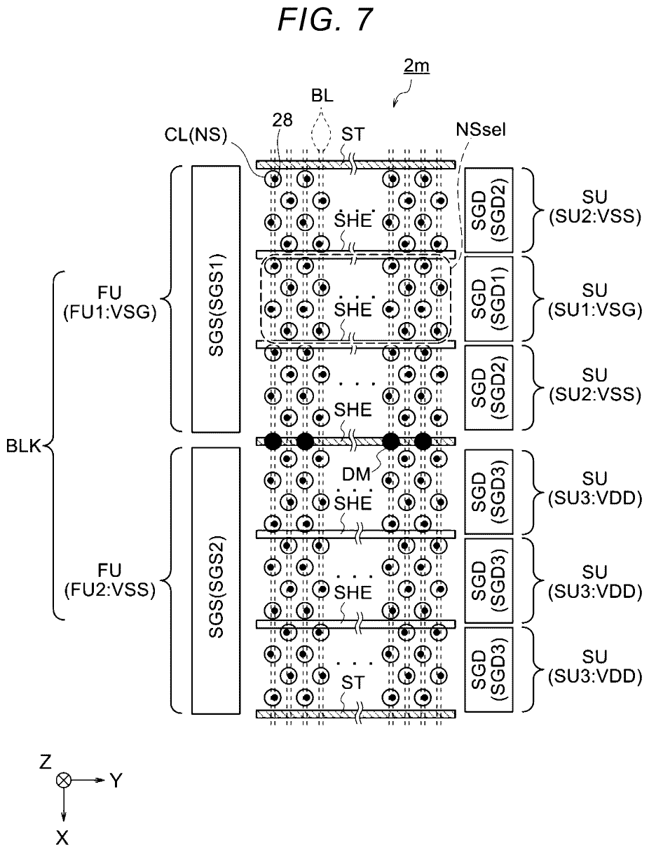

FIG. 7 is a plan view illustrating a plane of the memory cell array 2m according to the present embodiment and a method of controlling a read operation.

The memory cell array 2m includes the plurality of columnar bodies CL (that is, NAND strings NS). The plurality of NAND strings NS are divided for each block BLK by the slits ST. In the block BLK, the drain side select gate lines SGD of the plurality of NAND strings NS are divided for each string unit SU by the slits SHE. The plurality of string units (fingers) SU configure a finger unit FU. For example, FIG. 7 shows one block BLK, two finger units FU, and six string units SU. Three string units SU correspond to one finger unit FU. The number of blocks BLK, the number of finger units FU, and the number of string units SU are not limited. A dummy cell DM that does not function as the memory cell MC may be provided directly below the slit SHE between adjacent finger units FU.

The plurality of bit lines BL are provided in common for the plurality of string units SU and the plurality of finger units FU. The plurality of bit lines BL extend in the X direction perpendicular to the slits ST and SHE. The plurality of NAND strings NS in the same string unit SU are respectively connected to different bit lines BL through the vias 28. The bit line BL transmits data from the selected memory cell MC to the sense amplifier module 1016.

In the data read operation, the driver module 1014 and row decoder module 1015 in FIG. 1 perform selection operations and voltage driving of the word line WL, the drain side select gate line SGD, the source side select gate line SGS, and the like. The sense amplifier module 1016 detects the data from the memory cell array 2m through the bit line BL.

For example, in FIG. 7, the row decoder module 1015 selects a first finger unit FU1 to be read among the plurality of finger units FU. Further, the row decoder module 1015 selects a first string unit SU1 to be read among the plurality of string units SU in the first finger unit FU1.

Here, the driver module 1014 applies a first selection voltage VSG to a source side select gate line SGS1 corresponding to the first finger unit FU1 and a drain side select gate line SGD1 corresponding to the first string unit SU1. The first selection voltage VSG is a voltage higher than a first non-selection voltage VSS and a second non-selection voltage VDD. Thereby, although not illustrated in FIG. 7, the select transistor STS connected to the source side select gate line SGS1 transitions to a conductive state (ON state). The select transistor STD connected to the drain side select gate line SGD1 also transitions to a conductive state (ON state). Therefore, the plurality of string units SU in the first finger unit FU1 are selectively electrically connected to the source layer BSL. Furthermore, the plurality of NAND strings NS in the first string unit SU1 are selectively electrically connected to the plurality of bit lines BL. Thereby, a plurality of NAND strings NSsel in the first string unit SU1 are selectively electrically connected between the source layer BSL and the bit line BL. The plurality of NAND strings NSsel in the first string unit SU1 are respectively connected to different bit lines BL. Therefore, data of a selected memory cell connected to the selected word line WL among the plurality of memory cells in each NAND string NSsel is read through each corresponding bit line BL.

Meanwhile, the row decoder module 1015 does not select second string units SU2 other than the first string unit SU1 of the first finger unit FU1 such that the second string units SU2 are not to be read. Here, the driver module 1014 applies the first non-selection voltage VSS to drain side select gate lines SGD2 corresponding to the second string units SU2 in the first finger unit FU1. The first non-selection voltage VSS is a voltage lower than the first selection voltage VSG and the second non-selection voltage VDD. The first selection voltage VSG is, for example, a voltage of about 5 V, and is a voltage sufficiently higher than the threshold voltage of the memory cell MC. The first non-selection voltage VSS is, for example, a voltage of about 0 V, and is a voltage sufficiently lower than the threshold voltage of the memory cell MC. The second non-selection voltage VDD is, for example, a voltage of about 1.5 V. The select transistor STS connected to the source side select gate line SGS1 is in an ON state, and the select transistor STD connected to the drain side select gate line SGD2 transitions to a non-conductive state e (OFF state). Therefore, the second string units SU2 in the first finger unit FU1 are electrically connected to the source layer BSL but is electrically isolated from the bit line BL. Therefore, data is not read from the second string units SU2.

The row decoder module 1015 does not select a second finger unit FU2 of the plurality of finger units FU such that the second finger unit FU2 is not to be read. Here, the driver module 1014 applies the first non-selection voltage VSS to a source side select gate line SGS2 corresponding to the second finger unit FU2. Thereby, the select transistor STS connected to the source side select gate line SGS2 transitions to an OFF state. Therefore, the plurality of string units SU in the second finger unit FU2 are electrically isolated from the source layer BSL.

The driver module 1014 applies the second non-selection voltage VDD to a drain side select gate line SGD3 corresponding to the second finger unit FU2. The second non-selection voltage VDD is a voltage lower than the first selection voltage VSG and higher than the first non-selection voltage VSS. The select transistors STD and STS transition to an ON state by the first selection voltage VSG, and transition to an OFF state by the first and second non-selection voltages VSS and VDD. Therefore, the select transistor STD connected to the drain side select gate line SGD3 transitions to an OFF state. Thereby, the plurality of string units SU in the second finger unit FU2 are also electrically isolated from the bit line BL. Therefore, the channel (semiconductor body 210) of the memory cell of the NAND string NS in the second finger unit FU2 transitions to an electrically floating state.

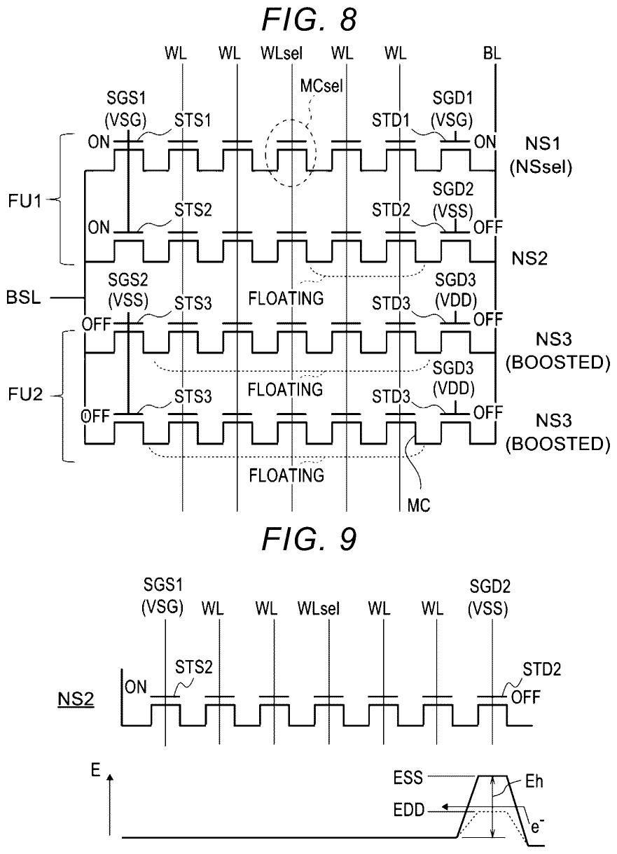

FIG. 8 is a diagram illustrating the NAND strings in the data read operation. A NAND string NS1 is the NAND string NSsel selected to be read. NAND strings NS2 and NS3 are non-selected NAND strings. The NAND string NS2 is a non-selected NAND string in the first finger unit FU1 to be read. The NAND string NS3 is a non-selected NAND string in the second finger unit FU2 not to be read.

As described above, the first selection voltage VSG is applied to the source side select gate line SGS1 and the drain side select gate line SGD1 of the NAND string NS1. Thereby, select transistors STS1 and STD1 transition to an ON state.

The driver module 1014 lowers a voltage of a selected word line WLsel to be read and raises a voltage of the other non-selected word lines WL not to be read. Thereby, in the NAND string NS1, only a selected memory cell MCsel connected to the selected word line WLsel transitions to an OFF state, and the non-selected memory cells MC connected to the other non-selected word lines WL transition to an ON state. In FIG. 8, the memory cells MC other than the memory cell MCsel are non-selected memory cells. Thereby, the selected memory cell MCsel is electrically connected between the source layer BSL and the bit line BL through the non-selected memory cell MC. As a result, the data stored in the selected memory cell MCsel is transmitted to the bit line BL.

In the NAND string NS2, the memory cell MC connected to the selected word line WLsel transitions to an OFF state, and the memory cells MC connected to the other non-selected word lines WL transition to an ON state. As a select transistor STS2 is in the ON state, the memory cells MC on the select transistor STS side of the memory cell MC connected to the selected word line WLsel are electrically connected to the source layer BSL. As a select transistor STD2 is in the OFF state, the memory cells MC on the select transistor STD side of the memory cell MC connected to the selected word line WLsel are electrically isolated from the source layer BSL and the bit line BL and transition to a floating state.

Also in the NAND string NS3 in the second finger unit FU2, the memory cell MC connected to the selected word line WLsel transitions to an OFF state, and the memory cells MC connected to the other non-selected word lines WL transition to an ON state. Select transistors STS3 and STD3 are both in an OFF state. Therefore, the memory cells MC in the NAND string NS3 are electrically isolated from the source layer BSL and the bit line BL and transition to a floating state.

In the NAND string NS3, the channels (semiconductor bodies 210) of all the memory cells MC transition to an electrically floating state. Thus, a voltage of the channel of the memory cell MC increases with an increase in voltage of the non-selected word line WL. Such an increase in voltage of the channel of the memory cell MC is referred to as a boost. That is, in the read operation, the channel of the memory cell MC in the NAND string NS3 in the non-selected second finger unit FU2 is boosted.

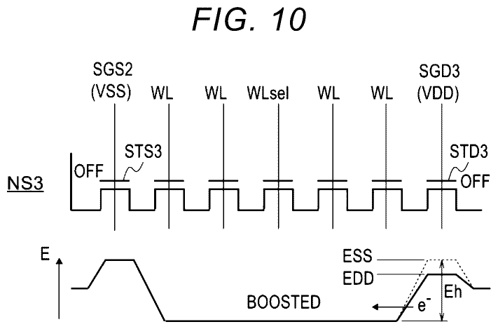

FIG. 9 is a diagram illustrating a state and a channel energy level of the NAND string NS2. FIG. 10 is a diagram illustrating a state and a channel energy level of the NAND string NS3. In an energy level graph on a lower side of each of FIGS. 9 and 10, a horizontal axis indicates a position of the NAND string, and a vertical axis indicates an energy level E. The energy level E indicates the energy level of electrons.

In the NAND string NS2 illustrated in FIG. 9, the channels of some of the memory cells MC transition to a floating state, while the source layer BSL is connected through the select transistor STS2. Therefore, the channel of the NAND string NS2 is less boosted by the voltage of the non-selected word line WL.

Here, when an off voltage of the drain side select gate line SGD2 is excessively high, a leakage current flowing through the select transistor STD2 increases. For example, when the voltage of the drain side select gate line SGD2 is the second non-selected voltage VDD higher than the first non-selected voltage VSS, as illustrated in FIG. 9, an energy barrier in the select transistor STD2 is lowered from ESS to EDD. Thereby, the leakage current can easily flow through the select transistor STD2, and the leakage current increases. Accordingly, it is preferable to set the voltage of the drain side select gate line SGD2 to the first non-selected voltage VSS lower than the second non-selected voltage VDD.

Meanwhile, in the NAND string NS3 illustrated in FIG. 10, the channels of all the memory cells MC transition to a floating state. Therefore, the channel of the NAND string NS3 is boosted to a voltage higher than the voltage of the NAND string NS2 by the voltage of the non-selected word line WL.

Here, when an off voltage of the drain side select gate line SGD3 is excessively low, the number of hot carriers (electrons) passing through the select transistor STD3 increases. For example, when the voltage of the drain side select gate line SGD3 is the first non-selection voltage VSS lower than the second non-selection voltage VDD, as illustrated in FIG. 10, the number of hot carriers tunneling through the energy barrier in the select transistor STD3 increases. Accordingly, it is preferable to set the voltage of the drain side select gate line SGD3 to the second non-selection voltage VDD higher than the first non-selection voltage VSS.

That is, when the voltage of the drain side select gate line SGD2 is equal to the voltage of the drain side select gate line SGD3, the leakage current flowing through the select transistor STD2 increases, or the number of hot carriers passing through the select transistor STD3 increases.

In contrast, in the present embodiment, the driver module 1014 causes a difference between the voltage of the drain side select gate line SGD2 of the non-selected NAND string NS2 in the first finger unit FU1 to be read and the voltage of the drain side select gate line SGD3 of the NAND string NS3 in the non-selected second finger unit FU2. Thereby, it is possible to reduce hot carriers in the select transistor STD3 while reducing the leakage current in the select transistor STD2.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a plurality of strings, each of the plurality of strings including a plurality of memory cells connected in series;
a plurality of first select transistors connected to one end of the plurality of strings, respectively;
a plurality of second select transistors connected to the other end of the plurality of strings, respectively;
a plurality of first control lines commonly provided to the plurality of strings and connected to respective gates of the memory cells of the plurality of strings;
a plurality of first selection lines connected to respective gates of the plurality of first select transistors and each corresponding to a first unit that includes one of the plurality of the strings;
a plurality of second selection lines connected to respective gates of the plurality of second select transistors and corresponding to a second unit that includes a plurality of the first units; and
a driver configured to provide, in a data read operation, a voltage for the plurality of first selection lines, causing a difference between a first non-selection voltage and a second non-selection voltage, wherein the first non-selection voltage is applied to one of the first selection lines not selected in a selected second unit which is selected to be read among a plurality of the second units, and the second non-selection voltage is applied to the first selection lines in one or more non-selected second units not to be read among the plurality of second units.

2. The semiconductor memory device according to claim 1, wherein the first non-selection voltage is lower than the second non-selection voltage.

3. The semiconductor memory device according to claim 1, wherein a first selection voltage, which is applied to another one of the first selection lines selected to be read in the selected second unit, is higher than the first non-selection voltage and the second non-selection voltage.

4. The semiconductor memory device according to claim 1, wherein a voltage, which is applied to the second selection lines corresponding to the selected second unit, is a first selection voltage.

5. The semiconductor memory device according to claim 1, wherein
one of the first select transistor selected to be read in the selected second unit transitions to a conductive state,
one or more of the first select transistors not selected in the selected second unit and one or more of the first select transistors in the one or more non-selected second units each transition to a non-conductive state,
the second select transistor in the selected second unit transitions to a conductive state, and
the second select transistors in the one or more non-selected second units each transition to a non-conductive state.

6. The semiconductor memory device according to claim 1, wherein
the plurality of first select transistors are electrically connected to a plurality of data lines that respectively transmit data from the memory cells, and
the plurality of second select transistors are electrically connected in common to a reference voltage layer to which a reference voltage is applied.

7. The semiconductor memory device according to claim 1, further comprising:
a stacked body including electrode films and first insulating films alternately stacked on top of one another in a first direction;
a plurality of first columnar bodies including semiconductor layers that penetrate the stacked body in the first direction;
a reference voltage layer commonly provided on one end side of the semiconductor layers of the plurality of first columnar bodies; and
a plurality of data lines provided on the other end side of the semiconductor layers of the plurality of first columnar bodies, wherein
the plurality of first select transistors are each connected between the semiconductor layers of the plurality of first columnar bodies and the plurality of data lines, and
the plurality of second select transistors are each connected between the semiconductor layers of the plurality of first columnar bodies and the reference voltage layer.

8. A method, comprising:
providing a semiconductor memory device including a plurality of strings each including a plurality of memory cells connected in series, a plurality of first select transistors each connected to the memory cells at one end of the plurality of strings, a plurality of second select transistors each connected to the memory cells at the other end of the plurality of strings, a plurality of first control lines commonly provided to the plurality of strings and each connected to respective gates of the plurality of memory cells, a plurality of first selection lines connected to respective gates of the plurality of first select transistors and each correspond to a first unit including one of the plurality of the strings, a plurality of second selection lines connected to respective gates of the plurality of second select transistors and each correspond to a second unit including a plurality of the first units;
applying, in a data read operation, a first non-selection voltage to one of the first selection lines not selected in a selected second unit which is selected to be read among a plurality of the second units; and
applying, in the data read operation, a second non-selection voltage different from the first non-selection voltage to the first selection lines in one or more non-selected second units not to be read among the plurality of second units.

9. The method according to claim 8, wherein the first non-selection voltage is lower than the second non-selection voltage.

10. The method according to claim 8, further comprising:
applying a first selection voltage to anther of the first selection line selected to be read in the selected second unit;
wherein the first selection voltage is higher than the first non-selection voltage and the second non-selection voltage.
